(19) United States
(12) Patent Application Publication
(10) Pub. No.: US 2024/0213930 A1
(43) Pub. Date: Jun. 27, 2024

(54) OVERCURRENT PROTECTION CIRCUIT AND POWER AMPLIFIER INCLUDING OVERCURRENT PROTECTION CIRCUIT

(71) Applicant: Samsung Electro-Mechanics Co., Ltd., Suwon-si (KR)

(72) Inventors: Youngwong JANG, Suwon-si (KR); Jeonghoon KIM, Suwon-si (KR); Shinichi IIZUKA, Suwon-si (KR); Jongok HA, Suwon-si (KR); Hyejin LEE, Suwon-si (KR)

(73) Assignee: Samsung Electro-Mechanics Co., Ltd., Suwon-si (KR)

(21) Appl. No.: 18/216,574

(22) Filed: Jun. 29, 2023

(30) Foreign Application Priority Data
Dec. 16, 2022 (KR) 10-2022-0177478

(51) Int. Cl. H03F 1/52; H02H 7/00; H03F 3/21

(52) U.S. Cl. CPC H03F 1/523; H02H 7/008; H03F 3/21; H03F 2200/451; H03F 2203/21127

(57) ABSTRACT

An overcurrent protection circuit includes a variable voltage source configured to generate a first voltage which that in response to a variable current; an amplifier comprising a first input terminal to which the first voltage is applied; and a limit current source connected to a second input terminal of the amplifier and configured to generate a limit current corresponding to the first voltage.

### CROSS-REFERENCE TO RELATED APPLICATIONS

This application claims the benefit under 35 USC 119(a) of Korean Patent Application No. 10-2022-0177478 filed on Dec. 16, 2022, in the Korean Intellectual Property Office, the entire disclosure of which is incorporated herein by reference.

### BACKGROUND

### 1. Field

This disclosure relates to an overcurrent protection circuit and a power amplifier including an overcurrent protection circuit.

### 2. Description of Related Art

A wireless communication system applies various digital modulation/demodulation methods in accordance with evolution of communication standards. The existing code division multiple access (CDMA) communication system employs a quadrature phase shift keying (QPSK) scheme and a wireless LAN according to the communication standard of IEEE employs an orthogonal frequency division multiplexing (OFDM) scheme. Furthermore, long term evolution (LTE) and LTE Advanced (LTE+), which are recent 3GPP standard specifications, employ QPSK, QAM (Quadrature Amplitude Modulation), and OFDM schemes.

In order to increase a transmission distance, a transmitting device used for a wireless communication system includes a power amplifier that amplifies a radio-frequency (RF) signal. The power amplifier may be designed to most efficiently operate at a rated voltage. When a load impedance of the power amplifier is changed, an overcurrent may flow, and thus there may be a situation in which the power amplifier transmits a power beyond its physical limitations. Accordingly, it is necessary to design a power amplifier that stably operates even in a situation in which an output current is applied over the design limitation.

A technique of limiting an output current of the power amplifier is referred to as overcurrent protection (OCP). As a method of implementing the OCP, there is a feedback method. According to the feedback method, the output current is sensed and a bias current is reduced in response to the sensed output current to limit the output current. However, according to the feedback method, the power amplifier may be broken by a delay time of a feedback loop.

The above information disclosed in this Background section is only for enhancement of understanding of the background of the disclosure of this application, and therefore it may contain information that does not constitute prior art that is already known to a person of ordinary skill in the art.

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

In one general aspect, an overcurrent protection circuit includes a variable voltage source configured to generate a first voltage that varies in response to a variable current; an amplifier including a first input terminal to which the first voltage is applied; and a limit current source connected to a second input terminal of the amplifier and configured to generate a limit current corresponding to the first voltage.

The variable voltage source may include a first transistor and a second transistor connected to each other in a current mirror structure; a variable current source connected between a first terminal of the first transistor and a ground and configured to generate the variable current; and a first resistor connected between a first terminal of the second transistor and the ground.

A voltage of the first terminal of the second transistor may be the first voltage.

The limit current source may be further connected to an output terminal of the amplifier, and a voltage of the output terminal of the amplifier may be a second voltage that varies in response to the variable current.

The limit current source may include a first transistor including a control terminal to which the second voltage is applied, and a first terminal connected to the second input terminal of the amplifier; a first resistor connected between the first terminal of the first transistor and a ground; and a second transistor including a control terminal to which the second voltage is applied, and a first terminal that outputs the limit current.

The limit current source may include a first transistor including a control terminal to which the second voltage is applied; a second transistor including a first terminal connected to a first terminal of the first transistor, and a second terminal connected to the second input terminal of the amplifier; a first resistor connected between the second terminal of the second transistor and a ground; a third transistor including a control terminal to which the second voltage is applied; and a fourth transistor including a first terminal connected to a first terminal of the third transistor, a control terminal connected to a control terminal of the second transistor, and a second terminal that outputs the limit current.

The limit current may vary in response to the first voltage and the second voltage.

The limit current may be generated to be supplied to a bias circuit configured to bias a power transistor.

The amplifier may be an operational amplifier, the first input terminal of the amplifier may be an inverting terminal of the operational amplifier, and the second input terminal of the amplifier may be a non-inverting terminal of the operational amplifier.

In another general aspect, a power amplifier includes a power transistor configured to amplify an input radio-frequency (RF) signal; a bias circuit configured to supply a bias current to the power transistor; and an overcurrent protection circuit configured to supply a limit current to the bias circuit to prevent an overcurrent from flowing in the power transistor, wherein the overcurrent protection circuit includes a variable voltage source configured to generate a first voltage that varies in response to a variable current; an amplifier including a first input terminal to which the first voltage is applied; and a limit current source connected to a second input terminal of the amplifier and configured to generate the limit current so that the limit current corresponds to the first voltage.

The variable voltage source may include a variable current source configured to generate the variable current; and a current mirror configured to generate a first current based on the variable current, generate the first voltage based on the first current so that the first voltage varies in response to the variable current.

The limit current source may be further connected to an output terminal of the amplifier, and a voltage of the output terminal of the amplifier may be a second voltage that varies in response to the variable current.

The limit current source may include a first transistor including a control terminal to which the second voltage is applied, and a first terminal connected to the second input terminal of the amplifier; a first resistor connected between the first terminal of the first transistor and a ground; and a second transistor including a control terminal to which the second voltage is applied, and a first terminal that outputs the limit current.

The limit current source may include a first transistor including a control terminal to which the second voltage is applied; a second transistor including a first terminal connected to a first terminal of the first transistor, and a second terminal connected to the second input terminal of the amplifier; a first resistor connected between the second terminal of the second transistor and a ground; a third transistor including a control terminal to which the second voltage is applied; and a fourth transistor including a first terminal connected to a first terminal of the third transistor, a control terminal connected to a control terminal of the second transistor, and a second terminal that outputs the limit current.

The limit current may vary in response to the first voltage and the second voltage.

In another general aspect, an overcurrent protection circuit includes a variable voltage source configured to generate a first voltage that varies in response to a variable current; an amplifier including a first input terminal to which the first voltage is applied; and a limit current source configured to generate a limit current corresponding to the first voltage, and apply a voltage corresponding to the limit current to a second input terminal of the amplifier.

The variable voltage source may include a first transistor and a second transistor connected to each other in a current mirror structure; a variable current source connected between a first terminal of the first transistor and a ground and configured to generate the variable current; and a first resistor connected between a first terminal of the second transistor and the ground.

A voltage of the first terminal of the second transistor may be the first voltage.

The limit current source may include a first transistor including a control terminal connected to an output terminal of the amplifier, and a first terminal providing the voltage corresponding to the limit current to the second input terminal of the amplifier; a first resistor connected between the first terminal of the first transistor and a ground; and a second transistor including a control terminal connected to the output terminal of the amplifier, and a first terminal that outputs the limit current.

The limit current source may include a first transistor including a control terminal connected to an output terminal of the amplifier; a second transistor including a first terminal connected to a first terminal of the first transistor, and a second terminal providing the voltage corresponding to the limit current to the second input terminal of the amplifier; a first resistor connected between the second terminal of the second transistor and a ground; a third transistor including a control terminal connected to the output terminal of the amplifier; and a fourth transistor including a first terminal connected to a first terminal of the third transistor, a control terminal connected to a control terminal of the second transistor, and a second terminal that outputs the limit current.

Other features and aspects will be apparent from the following detailed description, the drawings, and the claims.

### BRIEF DESCRIPTION OF DRAWINGS

FIG. 1 is a view illustrating a power amplifier according to one embodiment.

FIG. 2 is a view illustrating an example of a bias circuit of the power amplifier of FIG. 1 according to one embodiment.

FIG. 3 is a view illustrating an overcurrent protection circuit of the power amplifier of FIG. 1 according to one embodiment.

FIG. 4 is a circuit diagram illustrating an internal configuration of the overcurrent protection circuit of FIG. 3 according to one embodiment.

FIG. 5 is a view illustrating an example of a transistor M4 of the circuit diagram of FIG. 4 according to one embodiment.

FIG. 6 is a graph illustrating a relationship between a voltage V_{C} and a limit current I_{LIM} for the transistor M4 of FIG. 5 according to one embodiment.

FIG. 7 is a view illustrating a limit current source of the overcurrent protection circuit of FIG. 4 according to another embodiment.

Throughout the drawings and the detailed description, the same reference numerals refer to the same elements. The drawings may not be to scale, and the relative sizes, proportions, and depictions of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated by 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Through the specification, the RF signal may have a format according to any known wireless and wired protocols including Wi-Fi (IEEE 802.11 family), WiMAX (IEEE 802.16 family), IEEE 802.20, LTE (long term evolution), Ev-DO, HSPA+, HSDPA+, HSUPA+, EDGE, GSM, GPS, GPRS, CDMA, TDMA, DECT, Bluetooth, 3G, 4G, and 5G or higher, but is not limited thereto.

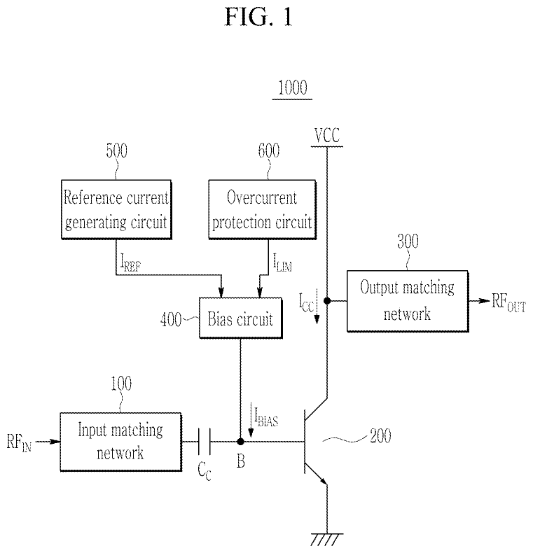

FIG. 1 is a view illustrating a power amplifier according to one embodiment.

As illustrated in FIG. 1, a power amplifier 1000 according to one embodiment includes an input matching network 100, a power transistor 200, an output matching network 300, a bias circuit 400, a reference current generating circuit 500, and an overcurrent protection circuit 600.

The input matching network 100 is connected to an input terminal (a base B) of the power transistor 200 and performs impedance matching between an input RF (radio-frequency) signal RF_{IN} and the power transistor 200. The output matching network 300 is connected to an output terminal (a collector C) of the power transistor 200 and performs impedance matching between an output RF signal RF_{OUT} and a next stage (that is, a next stage of the power amplifier). The input matching network 100 and the output matching network 300 may be implemented by a combination of one or more components selected from resistors, inductors, and capacitors.

The power transistor 200 amplifies the power of the RF signal RF_{IN} input to the input terminal (the base B) and then outputs the amplified power to the output terminal (the collector C). That is, an RF signal RF_{IN} to be amplified is input to the base B of the power transistor 200, and the collector C of the power transistor 200 outputs an amplified RF signal RF_{OUT}. An emitter E of the power transistor 200 may be connected to a ground, and even though it is not illustrated in FIG. 1, a resistor may be additionally connected between the emitter E of the power transistor 200 and the ground. The collector C of the power transistor 200 is connected to a power source voltage V_{CC} and the power transistor 200 operates by the power source voltage V_{CC}. In FIG. 1, a current flowing through the output terminal (that is, the collector C) of the power transistor 200 is denoted by I_{CC}. The current I_{CC} is an output current of the power amplifier 1000. The collector C of the power transistor 200 may be connected to the power source voltage V_{CC} through an inductor (not illustrated in FIG. 1) that serves as an RF choke.

In an abnormal state, in some cases, the current I_{CC} excessively increases. Examples of an abnormal state may be a case when a load impedance of the power transistor 200 significantly fluctuates, and a case when a battery providing the power source voltage V_{CC} is unstable. When the current I_{CC} excessively increases, the power transistor 200 may be damaged or destroyed. Hereinafter, when the current I_{CC} excessively increases, it is referred to as an “abnormal state,” and when the current I_{CC} does not excessively increase, it is referred to as a “normal state”. In order to prevent the abnormal state, the overcurrent protection circuit 600 according to one embodiment supplies a limit current I_{LIM} to the bias circuit 400 to protect the power transistor 200 from an overcurrent.

The power transistor 200 may be implemented by various transistors such as a heterojunction bipolar transistor (HBT), a bipolar junction transistor (BJT), and an insulated gate bipolar transistor (IGBT). Furthermore, in FIG. 1, the power transistor 200 is denoted as an N-type, but may be replaced with a P-type.

A coupling capacitor C_{C} is connected to the input terminal (the base B) of the power transistor 200. The coupling capacitor C_{C} performs a function of removing (blocking) a direct current (DC) component from the RF signal RF_{IN}.

The bias circuit 400 is supplied with a reference current I_{REF} from the reference current generating circuit 500, and is supplied with a limit current I_{LIM} from the overcurrent protection circuit 600. The bias circuit 400 generates a bias current I_{BIAS} needed by the power transistor 200 using the reference current I_{REF} and the limit current I_{LIM}. The bias current I_{BIAS} is supplied to the input terminal (the base B) of the power transistor 200 and a bias level (a bias point) of the power transistor 200 is set by the bias current I_{BIAS}. According to one embodiment, a maximum value of the bias current I_{BIAS} is limited by the limit current I_{LIM}, as will be described in more detail below.

The reference current generating circuit 500 generates a reference current I_{REF} and supplies the reference current to the bias circuit 400. As one example, the reference current generating circuit 500 generates different reference currents I_{REF} according to a power mode of the power amplifier 1000. When the power mode is a high power mode, the reference current generating circuit 500 generates a reference current I_{REF} HPM. When the power mode is a low power mode, the reference current generating circuit 500 generates a reference current I_{REF_LPM}. A magnitude of the reference current I_{REF} HPM may be larger than a magnitude of the reference current I_{REF_LPM}. In any event, the method of generating the reference current I_{REF} by the reference current generating circuit 500 is known to those skilled in the art, and accordingly a detailed description thereof will be omitted.

The overcurrent protection circuit 600 according to one embodiment generates the limit current I_{LIM} and supplies the generated limit current I_{LIM} to the bias circuit 400. As one example, the overcurrent protection circuit 600 may generate different limit currents I_{LIM} depending on the normal state or the abnormal state of the power amplifier 1000. In the normal state, the overcurrent protection circuit 600 generates a normal limit current I_{LIM_NS} in accordance with the bias circuit 400. That is, in the normal state, the overcurrent protection circuit 600 generates a normal limit current I_{LIM_NS} that is proportional to a need of the bias circuit 400. Furthermore, in the abnormal state, the overcurrent protection circuit 600 generates a limit current I_{LIM} that does not exceed an abnormal limit current I_{LIM_ABS}. That is, in the abnormal state, the overcurrent protection circuit 600 may generate a limit current I_{LIM} that does not exceed the abnormal limit current I_{LIM_ABS} regardless of the need of the bias circuit 400. In other words, the limit current I_{LIM} does not exceed the abnormal limit current I_{LIM_ABS}. Accordingly, a maximum range of the bias current I_{BIAS} of the bias circuit 400 is limited and the power amplifier 1000 is protected from an overcurrent.

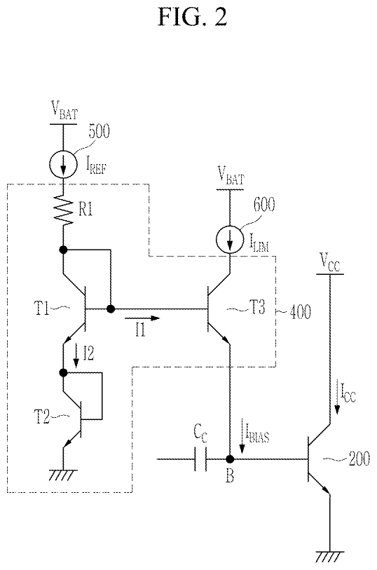

FIG. 2 is a view illustrating an example of a bias circuit of the power amplifier of FIG. 1 according to one embodiment.

As illustrated in FIG. 2, the bias circuit 400 includes a transistor T1, a transistor T2, a transistor T3, and a resistor R1.

The transistors T1 to T3 may be implemented by various transistors such as a heterojunction bipolar transistor (HBT), a bipolar junction transistor (BJT), and an insulated gate bipolar transistor (IGBT). Furthermore, in FIG. 2, the transistors T1 to T3 are denoted as an N-type, but may be replaced with a P-type.

A base and a collector of the transistor T1 are connected to each other in a diode-connected structure, and the collector of the transistor T1 is connected to a current source I_{REF} via the resistor R1. The transistor T1 sinks a current 12 from the current source I_{REF}. The reference current generating circuit 500 supplies the reference current I_{REF} to the bias circuit 400 so that in FIG. 2, the reference current generating circuit 500 is denoted as the current source I_{REF}.

A base and a collector of the transistor T2 are connected to each other in a diode-connected structure, and the collector of the transistor T2 is connected to an emitter of the transistor T1. An emitter of the transistor T2 is connected to the ground.

A collector of the transistor T3 is connected to a current sourceI_{LIM} and a base of the transistor T3 is connected to the base of the transistor T1. Furthermore, an emitter of the transistor T3 is connected to the input terminal (the base B) of the power transistor 200 and supplies the bias current I_{BIAS} to the power transistor 200. The overcurrent protection circuit 600 supplies the limit current I_{LIM} to the bias circuit 400 so that in FIG. 2, the overcurrent protection circuit 600 is denoted as the current source I_{LIM}.

The reference current I_{REF} is divided into a current 11 and the current 12, and the current 11 is input to the base of the transistor T3. Accordingly, the bias current I_{BIAS} is equal to a sum of the limit current I_{LIM} and the current 11. The bias current I_{BIAS} is the base current of the power transistor 200, so that the bias current I_{BIAS} and the current I_{CC} have a relationship defined by the following Equation 1.

$${I}_{BIAS} = \frac{{I}_{CC}}{β} \qquad ( 1 )$$

In Equation 1, β is a common-emitter current gain of the power transistor 200.

As described above, in the abnormal state, the value of the current I_{CC} increases. Referring to Equation 1, as the value of the current I_{CC} increases, a value of the bias current I_{BIAS} also increases. Therefore, the increase of the limit current I_{LIM} is needed. In this case, the overcurrent protection circuit 600 according to one embodiment is designed so that the limit current I_{LIM} does not exceed the abnormal limit current I_{LIM_ABS}. The overcurrent protection circuit 600 that performs the above-described operation will be described in more detail below.

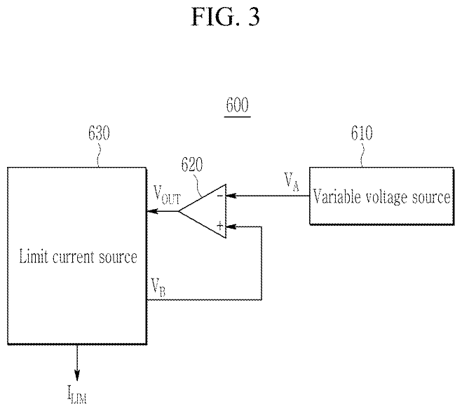

FIG. 3 is a view illustrating an overcurrent protection circuit of the power amplifier of FIG. 1 according to one embodiment.

As illustrated in FIG. 3, the overcurrent protection circuit 600 according to one embodiment includes a variable voltage source 610, an amplifier 620, and a limit current source 630.

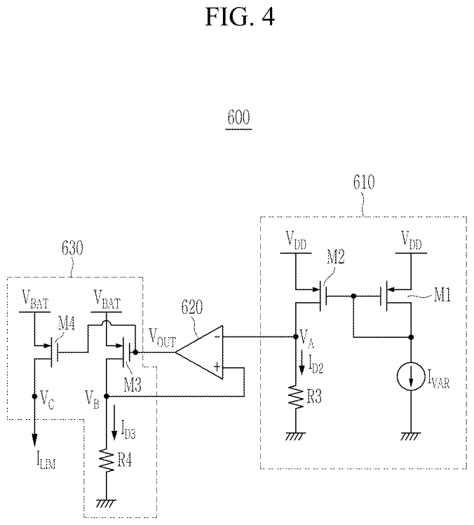

The variable voltage source 610 generates and outputs a voltage V_{A} that fluctuates in response to an internal variable current source I_{VAR} (see FIG. 4).

The amplifier 620 receives the voltage V_{A} output from the variable voltage source 610 through an inverting terminal (−). That is, the voltage V_{A} is applied to the inverting terminal (−) of the amplifier 620. A voltage V_{B} is output from the limit current source 630 and is applied to a non-inverting terminal (+) of the amplifier 620. The amplifier 620 outputs a voltage V_{OUT} from an output terminal of the amplifier 620, and the voltage V_{OUT} is applied to the limit current source 630. The amplifier 620 may be an operational amplifier (OP AMP). The voltage V_{B} may be set to be equal to the voltage V_{A} by the operation of the amplifier 620. Furthermore, by the operation of the amplifier 620, the voltage V_{OUT} may be set so that the voltage V_{A} and the voltage V_{B} become the same voltage. The voltage V_{A} is variable so that the voltage V_{OUT} is also variable, i.e., it fluctuates.

The limit current source 630 generates the limit current I_{LIM} in response to the voltage V_{OUT} applied from the amplifier 620 and the voltage V_{B} applied to the amplifier 620. The limit current I_{LIM} generated in the limit current source 630 is supplied (applied) to the bias circuit 400.

FIG. 4 is a circuit diagram illustrating an internal configuration of the overcurrent protection circuit of FIG. 3 according to one embodiment.

As illustrated in FIG. 4, the variable voltage source 610 according to one embodiment includes a transistor M1, a transistor M2, a variable current source I_{VAR}, and a resistor R3. Furthermore, the limit current source 630 according to one embodiment includes a transistor M3, a transistor M4, and a resistor R4.

In FIG. 4, the transistor M1, the transistor M2, the transistor M3, and the transistor M4 may be various transistors such as a field-effect transistor (FET) and a bipolar transistor. Furthermore, in FIG. 4, the transistor M1, the transistor M2, the transistor M3, and the transistor M4 are denoted as P-types, but may also be N-types. In the following description, for the sake of convenience, the transistor M1, the transistor M2, the transistor M3, and the transistor M4 are assumed to be FETs, but may be replaced with another type of transistor. A gate (control terminal) of the transistor serves as a control terminal so that the term 'control terminal is used therefor. A source of the transistor is one terminal of the transistor so that the term first terminal or second terminal may be used therefore. Furthermore, a drain of the transistor is another terminal of the transistor so that the term second terminal or first terminal may be used therefor.

The source of the transistor M1 is connected to a power source voltage V_{DD} and a gate (control terminal) and a drain of the transistor M1 are connected to each other. One end of the variable current source I_{VAR} is connected to the drain of the transistor M1 and the other end of the variable current source I_{VAR} is connected to the ground. A gate (control terminal) of the transistor M2 is connected to the gate (control terminal) of the transistor M1, and a source of the transistor M2 is connected to the power source voltage V_{DD}. The resistor R3 is connected between a drain of the transistor M2 and the ground. The transistor M1 and the transistor M2 are connected to each other in a current mirror structure. In FIG. 4, a voltage at a junction between the drain of the transistor M2 and the resistor R3 is denoted as a voltage V_{A}. The power source voltage V_{DD} is output from a regulator circuit, for example, a low-dropout (LDO) regulator circuit.

The variable current source I_{VAR} according to one embodiment generates and outputs a variable current I_{VAR}. As an example, the variable current source I_{VAR} may generate a variable current I_{VAR} having different current values depending on a power mode of the power amplifier 1000. When the power mode is a high power mode, the variable current source I_{VAR} may generate a current I_{VAR_HPM}. When the power mode is a low power mode, the variable current source I_{VAR} may generate a current I_{VAR_LPM}. A magnitude of the current I_{VAR_HPM} may be larger than a magnitude of the current I_{VAR_LPM}.

Since the variable current source I_{VAR} has a variable current value, a voltage V_{A} value is also variable (fluctuates). The transistor M1 and the transistor M2 have a current mirror structure so that a drain current I_{D2} of the transistor M2 is proportional to a size ratio of the transistor M1 and the transistor M2 (a ratio of a channel width and a channel length). That is, the drain current I_{D2} of the transistor M2 has a relationship defined by the following Equation 2.

I_{D2}=K1×I_{VAR} (2)

In Equation 2, K1 refers to a size ratio of the transistor M1 and the transistor M2. As an example, when a size of the transistor M1 is equal to a size of the transistor M2, K1 is 1. When K is 1, the drain current I_{D2} of the transistor M2 is equal to the current I_{VAR} generated by the variable current source I_{VAR}.

The voltage V_{A} is defined by the following Equation 3.

V_{A}=R3×I_{D2}=R3·K1·I_{VAR} (3)

Referring to Equation 3, the voltage V_{A} may vary (fluctuate) according to a value of the variable current I_{VAR}. The voltage V_{B} is set to be equal to the voltage V_{A} by the amplifier 620. Furthermore, by the operation of the amplifier 620, the voltage V_{OUT} may be set so that the voltage V_{A} and the voltage V_{B} become the same voltage. Accordingly, the voltage V_{OUT} may also vary (fluctuate) according to the value of the variable current I_{VAR}.

Referring to FIG. 4, the gate (control terminal) of the transistor M3 and the gate (control terminal) of the transistor M4 are connected to the output terminal of the amplifier 620. That is, the voltage V_{OUT} is applied to the gate (control terminal) of the transistor M3 and the gate (control terminal) of the transistor M4. A source of the transistor M3 and a source of the transistor M4 are connected to a power source voltage V_{BAT}. As an example, the power source voltage V_{BAT} may be a battery voltage. A drain of the transistor M3 is connected to the non-inverting terminal (+) of the amplifier 620. The resistor R4 is connected between the non-inverting terminal (+) (that is, the drain of the transistor M3) of the amplifier 620 and the ground. A drain current I_{D3} of the transistor M3 is defined by the following Equation 4.

$${I}_{D 3} = \frac{{V}_{B}}{R 4} = \frac{R 3}{R 4} \cdot K 1 \cdot {I}_{VAR} \qquad ( 4 )$$

The voltage V_{B} in Equation 4 is equal to the voltage V_{A}, so that the voltage V_{B} in Equation 4 may be replaced by Equation 3 for the voltage V_{A}.

In FIG. 4, a drain current of the transistor M4 is the above-described limit current I_{LIM}. That is, a drain of the transistor M4 may supply the limit current I_{LIM} to the bias circuit 400. The gate (control terminal) of the transistor M3 and the gate (control terminal) of the transistor M4 are connected to each other and to the output terminal of the amplifier 620. Accordingly, when the transistor M3 and the transistor M4 operate in a saturation region, the transistor M3 and the transistor M4 operate as a current mirror. Accordingly, the limit current I_{LIM} is defined by the following Equation 5.

I_{LIM}=K2×I_{D3} (5)

In Equation 5, K2 refers to a size ratio of the transistor M3 and the transistor M4. As one example, when the size of the transistor M4 is 20 times larger than the size of the transistor M3, K2 is 20.

In Equation 5, instead of the drain current I_{D3} of the transistor M3, when Equation 4 is applied, the limit current I_{LIM} is defined by the following Equation 6.

$${I}_{LIM} = \frac{R 3}{R 4} \cdot K 1 \cdot K 2 \cdot {I}_{VAR} \qquad ( 6 )$$

In Equation 6, values of K1 and K2 and values of resistances R3 and R4 may be set in advance according to a design of the power amplifier 1000. The limit current I_{LIM} may have different values depending on the value of the variable current I_{VAR}. As described above, the variable current I_{VAR} has different values depending on the power mode of the power amplifier 1000 so that value of the limit current I_{LIM} also has different values depending on the power mode.

Referring to Equation 6, the value of the limit current I_{LIM} is affected by the values of the resistances R3 and R4. In the overcurrent protection circuit 600 according to one embodiment, the resistors R3 and R3 are manufactured by the same process so that the limit current I_{LIM} may be less affected by deviations in the values of the resistors.

In the limit current source 630, the transistor M3 may be designed to operate in the saturation region at all times. In contrast, the transistor M4 may operate in different modes depending on a drain voltage V_{C} of the transistor M4. The drain voltage V_{C} of the transistor M4 may be a collector voltage of the transistor T3 in FIG. 2. Accordingly, the transistor M4 may operate in different modes depending on a normal state and an abnormal state of the power amplifier 1000.

As one example, in the normal state, the transistor M4 operates in a triode region, and in the abnormal state, the transistor M4 operates in the saturation region. When the transistor M4 operates in the triode region, the value of the limit current I_{LIM} may vary in response to the drain voltage V_{C} of the transistor M4. When the transistor M4 operates in the saturation region, the value of the limit current I_{LIM} has a value defined by Equation 6. In the abnormal state, the value of the current I_{CC} increases. In this case, the transistor M4 of the overcurrent protection circuit 600 operates in the saturation region and the value of the limit current I_{LIM} may have a value defined by Equation 6. That is, the above described abnormal limit current I_{LIM_ABS} may be designed to have a value defined by Equation 6. By doing this, the overcurrent protection circuit 600 may prevent the damage due to the overcurrent of the power transistor 200.

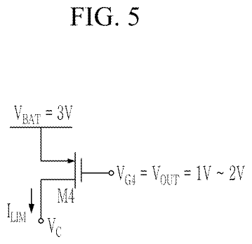

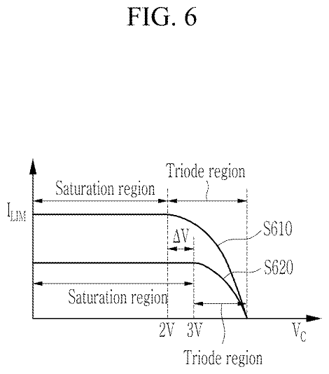

According to Equation 3, the voltage V_{OUT}, which is the output voltage of the output terminal of the amplifier 620, may vary (fluctuate) according to a value of the variable current source I_{VAR}. The voltage V_{OUT} is a gate (control terminal) voltage of the transistor M4 so that a headroom of the transistor M4 may expand. That is, in the overcurrent protection circuit 600 according to one embodiment, the gate (control terminal) voltage of the transistor M4 is not fixed, but may vary so that the headroom of the transistor M4 may expand. The headroom refers to a range of a drain-source voltage (Vds) of a transistor to allow the transistor to operate in the saturation region. This will be described below with reference to FIGS. 5 and 6.

FIG. 5 is a view illustrating an example of a transistor M4 of the circuit diagram of FIG. 4 according to one embodiment. Furthermore, FIG. 6 is a graph illustrating a relationship between a voltage V_{C} and a limit current I_{LIM} for the transistor M4 of FIG. 5 according to one embodiment.

In FIG. 5, it is assumed that the power source voltage V_{BAT} is 3 V and a gate (control terminal) voltage V_{G4} of the transistor M4 between 1 V and 2 V. That is, the value of the variable current I_{VAR} fluctuates so that as one example, the gate (control terminal) voltage V_{G4} (that is, the voltage V_{OUT}) of the transistor M4 may vary between 1 V and 2 V. In FIG. 6, S610 represents a relationship between the voltage V_{C} and the limit current I_{LIM} when the gate (control terminal) voltage V_{G4} is 1 V and S620 represents a relationship between the voltage V_{C} and the limit current I_{LIM} when the gate (control terminal) voltage V_{G4} is 2 V.

When the gate (control terminal) voltage V_{G4} of the transistor M4 is 1 V, if the voltage V_{C} is equal to or lower than 2 V, the transistor M4 operates in the saturation region. That is, when the voltage V_{C} has a range of 0 V to 2 V, the transistor M4 operates in the saturation region.

When the gate (control terminal) voltage V_{G4} of the transistor M4 is 2 V, if the voltage V_{C} is equal to or lower than 3 V, the transistor M4 operates in the saturation region. That is, when the voltage V_{C} has a range of 0 V to 3 V, the transistor M4 operates in the saturation region. In other words, when the gate (control terminal) voltage V_{G4} increases from 1 V to 2 V, a range of the drain-source voltage at which the transistor M4 operates in the saturation region expands. Accordingly, in one embodiment, the headroom of the transistor M4 expands.

Referring to FIG. 6, a range of the voltage V_{C} at which the transistor M4 operates in the saturation region in S620 expands by ΔV from a range of the voltage V_{C} at which the transistor M4 operates in the saturation region n S610. That is, in the overcurrent protection circuit 600 according to one embodiment, the gate (control terminal) voltage of the transistor M4 is not fixed, but may fluctuate so that the headroom of the transistor M4 may expand. As described above, the headroom of the transistor M4 expands so that the overcurrent protection circuit 600 according to one embodiment may supply a stable limit current I_{LIM} to the bias circuit 400. That is, according to one embodiment, the headroom of the transistor M4 used to generate the limit current expands to stably limit the output current of the power amplifier.

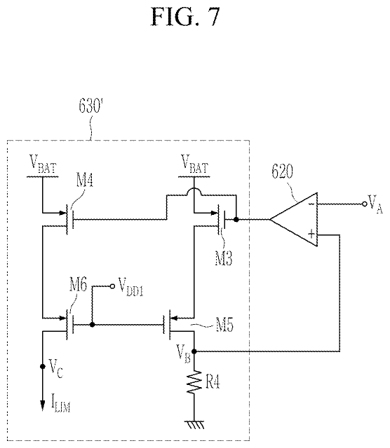

FIG. 7 is a view illustrating a limit current source of the overcurrent protection circuit of FIG. 4 according to another embodiment.

As illustrated in FIG. 7, a limit current source 630′ according to another embodiment is similar to the limit current source 630 of FIG. 4 except that in the limit current source 630 of FIG. 7, a transistor M5 and a transistor M6 are added.

A source of the transistor M5 is connected to the drain of the transistor M3 so that a drain of the transistor M5 may be connected to the non-inverting terminal (+) of the amplifier 620. A source of the transistor M6 is connected to the drain of the transistor M4 and a limit current I_{LIM} is output from the drain of the transistor M6. A gate (control terminal) of the transistor M5 and a gate (control terminal) of the transistor M6 are connected to each other, and a power source voltage V_{DD1} is applied to the gate (control terminal) of the transistor M5 and the gate (control terminal) of the transistor M6 as a bias voltage.

That is, the transistor M5 is connected to the transistor M3 in a cascode structure, and the transistor M6 is connected to the transistor M4 in a cascode structure. Due to this cascode structure, a channel resistance of the limit current source 630′ of FIG. 7 may be increased as compared with the limit current source 630 of FIG. 4. When the channel resistance is increased, the limit current I_{LIM} may be less affected by the change in the voltage V_{C}. The voltage V_{C} is the collector voltage of the transistor T3 in FIG. 2 so that the limit current source 630′ according to another embodiment may supply a stable limit current I_{LIM} even when the collector voltage V_{C} of the transistor T3 changes.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and are not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. An overcurrent protection circuit comprising:
a variable voltage source configured to generate a first voltage that varies in response to a variable current;
an amplifier comprising a first input terminal to which the first voltage is applied; and
a limit current source connected to a second input terminal of the amplifier and configured to generate a limit current corresponding to the first voltage.

2. The overcurrent protection circuit of claim 1, wherein the variable voltage source comprises:
a first transistor and a second transistor connected to each other in a current mirror structure;
a variable current source connected between a first terminal of the first transistor and a ground and configured to generate the variable current; and
a first resistor connected between a first terminal of the second transistor and the ground.

3. The overcurrent protection circuit of claim 2, wherein a voltage of the first terminal of the second transistor is the first voltage.

4. The overcurrent protection circuit of claim 1, wherein the limit current source is further connected to an output terminal of the amplifier, and
a voltage of the output terminal of the amplifier is a second voltage that varies in response to the variable current.

5. The overcurrent protection circuit of claim 4, wherein the limit current source comprises:
a first transistor comprising a control terminal to which the second voltage is applied, and a first terminal connected to the second input terminal of the amplifier;
a first resistor connected between the first terminal of the first transistor and a ground; and
a second transistor comprising a control terminal to which the second voltage is applied, and a first terminal that outputs the limit current.

6. The overcurrent protection circuit of claim 4, wherein the limit current source comprises:
a first transistor comprising a control terminal to which the second voltage is applied;
a second transistor comprising a first terminal connected to a first terminal of the first transistor, and a second terminal connected to the second input terminal of the amplifier;
a first resistor connected between the second terminal of the second transistor and a ground;
a third transistor comprising a control terminal to which the second voltage is applied; and
a fourth transistor comprising a first terminal connected to a first terminal of the third transistor, a control terminal connected to a control terminal of the second transistor, and a second terminal that outputs the limit current.

7. The overcurrent protection circuit of claim 4, wherein the limit current varies in response to the first voltage and the second voltage.

8. The overcurrent protection circuit of claim 1, wherein the limit current is generated to be supplied to a bias circuit configured to bias a power transistor.

9. The overcurrent protection circuit of claim 1, wherein the amplifier is an operational amplifier, the first input terminal of the amplifier is an inverting terminal of the operational amplifier, and the second input terminal of the amplifier is a non-inverting terminal of the operational amplifier.

10. A power amplifier comprising:
a power transistor configured to amplify an input radio-frequency (RF) signal;
a bias circuit configured to supply a bias current to the power transistor; and
an overcurrent protection circuit configured to supply a limit current to the bias circuit to prevent an overcurrent from flowing in the power transistor,
wherein the overcurrent protection circuit comprises:
a variable voltage source configured to generate a first voltage that varies in response to a variable current;
an amplifier comprising a first input terminal to which the first voltage is applied; and
a limit current source connected to a second input terminal of the amplifier and configured to generate the limit current so that the limit current corresponds to the first voltage.

11. The power amplifier of claim 10, wherein the variable voltage source comprises:
a variable current source configured to generate the variable current; and
a current mirror configured to generate a first current based on the variable current, generate the first voltage based on the first current so that the first voltage varies in response to the variable current.

12. The power amplifier of claim 10, wherein the limit current source is further connected to an output terminal of the amplifier, and
a voltage of the output terminal of the amplifier is a second voltage that varies in response to the variable current.

13. The power amplifier of claim 12, wherein the limit current source comprises:
a first transistor comprising a control terminal to which the second voltage is applied, and a first terminal connected to the second input terminal of the amplifier;
a first resistor connected between the first terminal of the first transistor and a ground; and
a second transistor comprising a control terminal to which the second voltage is applied, and a first terminal that outputs the limit current.

14. The power amplifier of claim 12, wherein the limit current source comprises:
a first transistor comprising a control terminal to which the second voltage is applied;
a second transistor comprising a first terminal connected to a first terminal of the first transistor, and a second terminal connected to the second input terminal of the amplifier;
a first resistor connected between the second terminal of the second transistor and a ground;
a third transistor comprising a control terminal to which the second voltage is applied; and
a fourth transistor comprising a first terminal connected to a first terminal of the third transistor, a control terminal connected to a control terminal of the second transistor, and a second terminal that outputs the limit current.

15. The power amplifier of claim 12, wherein the limit current varies in response to the first voltage and the second voltage.

16. An overcurrent protection circuit comprising:
a variable voltage source configured to generate a first voltage that varies in response to a variable current;
an amplifier comprising a first input terminal to which the first voltage is applied; and
a limit current source configured to generate a limit current corresponding to the first voltage, and apply a voltage corresponding to the limit current to a second input terminal of the amplifier.

17. The overcurrent protection circuit of claim 16, wherein the variable voltage source comprises:
a first transistor and a second transistor connected to each other in a current mirror structure;
a variable current source connected between a first terminal of the first transistor and a ground and configured to generate the variable current; and
a first resistor connected between a first terminal of the second transistor and the ground.

18. The overcurrent protection circuit of claim 17, wherein a voltage of the first terminal of the second transistor is the first voltage.

19. The overcurrent protection circuit of claim 16, wherein the limit current source comprises:
a first transistor comprising a control terminal connected to an output terminal of the amplifier, and a first terminal providing the voltage corresponding to the limit current to the second input terminal of the amplifier;
a first resistor connected between the first terminal of the first transistor and a ground; and
a second transistor comprising a control terminal connected to the output terminal of the amplifier, and a first terminal that outputs the limit current.

20. The overcurrent protection circuit of claim 16, wherein the limit current source comprises:
a first transistor comprising a control terminal connected to an output terminal of the amplifier;
a second transistor comprising a first terminal connected to a first terminal of the first transistor, and a second terminal providing the voltage corresponding to the limit current to the second input terminal of the amplifier;
a first resistor connected between the second terminal of the second transistor and a ground;
a third transistor comprising a control terminal connected to the output terminal of the amplifier; and
a fourth transistor comprising a first terminal connected to a first terminal of the third transistor, a control terminal connected to a control terminal of the second transistor, and a second terminal that outputs the limit current.
